(19) United States
(12) Patent Application Publication
(10) Pub. No.: US 2024/0222987 A1
(43) Pub. Date: Jul. 4, 2024

(54) WIRELESS CHARGING DEVICE

(71) Applicant: HONOR DEVICE CO., LTD., Shenzhen (CN)

(72) Inventors: Hua HUANG, Shenzhen (CN); Xialing ZHANG, Shenzhen (CN); Xiaoyong ZHU, Shenzhen (CN); Anle ZHANG, Shenzhen (CN)

(21) Appl. No.: 18/025,160

(22) PCT Filed: Aug. 24, 2022
(86) PCT No.: PCT/CN2022/114626

§ 371 Date: Jun. 22, 2023

(30) Foreign Application Priority Data
Dec. 14, 2021 (CN) 202123159198.2

(51) Int. Cl. H02J 7/00; H02J 50/00; H02J 50/10; H05K 7/20

(52) U.S. Cl. CPC H02J 7/00309; H02J 7/0044; H02J 50/005; H02J 50/10; H05K 7/20145

(57) ABSTRACT

This application provides a wireless charging device for charging an electronic device. The wireless charging device includes a housing, a transmit coil, and a heat dissipation assembly. The housing is provided with a panel. The transmit coil is disposed in the housing, and is located on a side of the panel. The housing is configured to place an electronic device to be charged, and the electronic device is at a distance from the panel. The housing is provided with an air vent located under the panel. The heat dissipation assembly includes a semiconductor refrigeration chip and a fan. The semiconductor refrigeration chip includes a cold end and a hot end. The hot end is disposed on the housing. The fan is disposed on the housing, and air blown by the fan passes through the cold end and is blown out from the air vent.

### CROSS-REFERENCE TO RELATED APPLICATIONS

This application claims priority to Chinese Patent Application No. 202123159198.2, filed with the China National Intellectual Property Administration on Dec. 14, 2021 and entitled “WIRELESS CHARGING DEVICE”, which is incorporated herein by reference in its entirety.

### TECHNICAL FIELD

Embodiments of this application relate to the field of wireless charging technologies, and in particular, to a wireless charging device.

### BACKGROUND

In a wireless charging process of an electronic device, a large amount of heat is generated by the electronic device. If charging time is relatively long, the heat may cause damage to both the electronic device and a wireless charging device. An existing low-power wireless charging device is not provided with a heat dissipation structure, or dissipates heat of the electronic device by being in contact with a heat sink; and a high-power wireless charging device dissipates heat of the electronic device by using a fan. However, a heat dissipation effect is not ideal, and needs to be further optimized.

### SUMMARY

In view of this, this application provides a wireless charging device with a good heat dissipation effect.

According to a first aspect, this application provides a wireless charging device for charging an electronic device. The wireless charging device includes a housing, a transmit coil, and a heat dissipation assembly. The housing is provided with a panel. The transmit coil is disposed in the housing, and is located on a side of the panel. The housing is configured to place an electronic device to be charged, and the electronic device is at a distance from the panel. The housing is provided with an air vent located under the panel. The heat dissipation assembly includes a semiconductor refrigeration chip and a fan. The semiconductor refrigeration chip includes a cold end and a hot end. The hot end is disposed on the housing. The fan is disposed on the housing, and air blown by the fan passes through the cold end and is blown out from the air vent.

The air blown by the fan passes through the cold end and a temperature of the air is reduced, and the air passes between the panel and the electronic device to reduce a temperature of the electronic device.

In a possible implementation, the heat dissipation assembly further includes another fan and a first thermally conductive member. The first thermally conductive member is disposed on a side that is of the transmit coil and that is away from the panel; and the another fan is disposed on the housing, and blows air to the first thermally conductive member.

Apparently, in the foregoing implementation, the air blown by the another fan can be blown to the first thermally conductive member, so as to reduce a temperature of the first thermally conductive member, and then reduce a temperature of the transmit coil.

In a possible implementation, the first thermally conductive member is obliquely disposed above the another fan, and the another fan blows air from an upper side.

Apparently, in the foregoing implementation, the first thermally conductive member is obliquely disposed above the fan, to increase projection of the first thermally conductive member on the fan, so that the air blown by the fan may be directly blown to a larger area of the first thermally conductive member, thereby improving efficiency of reducing the temperature of the first thermally conductive member.

In a possible implementation, the heat dissipation assembly further includes another semiconductor refrigeration chip, and the another semiconductor refrigeration chip is disposed between the transmit coil and the first thermally conductive member, and the cold end faces the transmit coil and the hot end faces the first thermally conductive member.

Apparently, in the foregoing implementation, the another semiconductor refrigeration chip is disposed between the transmit coil and the first thermally conductive member, thereby further improving cooling efficiency of the transmit coil.

In a possible implementation, a first cavity and a second cavity are disposed in the housing, and the second cavity is located above the first cavity. The fan and the another fan are disposed in the first cavity. The transmit coil, the semiconductor refrigeration chip, and the first thermally conductive member are sequentially disposed in the second cavity.

Apparently, in the foregoing implementation, the air blown by the fan and the air blown by the another fan are respectively blown to the first thermally conductive member and between the electronic device and the panel, so that both the electronic device and the wireless charging device are cooled, thereby improving cooling efficiency.

In a possible implementation, the first cavity includes a first segment and a second segment, the second segment extends upward along a curve from the first segment to the air vent, the fan is located in the first segment, and the semiconductor refrigeration chip is located in the second segment.

Apparently, in the foregoing implementation, the second segment extends upward along a curve from the first segment to the air vent, so as to guide the air blown by the fan to be blown out from the air vent, and reduce a force of the air blown by the air vent on the electronic device placed on the housing.

In a possible implementation, the wireless charging device further includes a circuit board, the housing is further provided with a third cavity and an air exhaust vent that communicate with each other, and the third cavity communicates with both the first cavity and the second cavity. The third cavity is located above the first cavity, and is located on a side of the second cavity. The circuit board is electrically connected to the transmit coil, the fan, and the another fan. The circuit board is disposed on the housing, and is located in the third cavity. The air blown by the another fan can be blown to the first thermally conductive member and the circuit board, and is discharged from the air exhaust vent.

Apparently, in the foregoing implementation, the another fan can also blow air to the circuit board, so that a temperature of the circuit board is reduced, and a cooling effect of the wireless charging device is further improved.

According to a second aspect, this application provides a wireless charging device, where the wireless charging device includes a housing, a transmit coil, and a heat dissipation assembly. The housing is provided with a panel. The heat dissipation assembly includes a semiconductor refrigeration chip, a first thermally conductive member, and a fan. The semiconductor refrigeration chip includes a cold end and a hot end. The panel, the transmit coil, the semiconductor refrigeration chip, and the first thermally conductive member are sequentially stacked. The cold end faces the transmit coil, and the hot end faces the first thermally conductive member. The fan is disposed in the housing, and the first thermally conductive member is obliquely disposed above the fan.

The air blown by the fan reduces a temperature of the first thermally conductive member, to improve a cooling effect of a cold end of the semiconductor refrigeration chip that is in contact with the first thermally conductive member, and reduce temperatures of the transmit coil and the panel that are sequentially in contact with the cold end, thereby reducing a temperature of the electronic device that is in contact with the panel.

In a possible implementation, a first cavity and a second cavity are disposed in the housing, and the second cavity is located above the first cavity. The fan is located in the first cavity. The transmit coil, the semiconductor refrigeration chip, and the first thermally conductive member are sequentially disposed in the second cavity.

Apparently, in the foregoing implementation, the third cavity is located above the first cavity, and is located on a side of the second cavity, to enable the air blown by the fan to enter the third cavity from the first cavity and be directly blown to the first thermally conductive member, so as to effectively reduce a temperature of the hot end of the semiconductor refrigeration chip, so that a temperature of the cold end of the semiconductor refrigeration chip is maintained at a lower temperature, or a low-temperature state is maintained for a longer time.

In a possible implementation, the wireless charging device further includes a circuit board, the housing is further provided with a third cavity and an air exhaust vent that communicate with each other, and the third cavity communicates with both the first cavity and the second cavity. The third cavity is located above the first cavity, and is located on a side of the second cavity. The circuit board is electrically connected to the transmit coil and the fan. The circuit board is disposed on the housing, and is located in the third cavity. The air blown by the fan can be blown to the first thermally conductive member and the circuit board, and is discharged from the air exhaust vent.

Apparently, in the foregoing implementation, the fan can also blow air to the circuit board, so that a temperature of the circuit board is reduced, and a cooling effect of the wireless charging device is further improved.

In a possible implementation, the wireless charging device further includes a second thermally conductive member, and the second thermally conductive member is disposed between the transmit coil and the semiconductor refrigeration chip.

Apparently, in the foregoing implementation, when an area of the cold end of the semiconductor refrigeration chip parallel to the panel is smaller than an area of the second thermally conductive member parallel to the panel, the second thermally conductive member can conduct all heat of the transmit coil parallel to a surface of the panel, and then conduct the heat to the semiconductor refrigeration chip, thereby improving cooling efficiency.

In a possible implementation, the heat dissipation assembly further includes a third thermally conductive member, and the third thermally conductive member is disposed between the semiconductor refrigeration chip and the first thermally conductive member.

Apparently, in the foregoing implementation, when an area of the hot end of the semiconductor refrigeration chip parallel to the panel is smaller than an area of the third thermally conductive member parallel to the panel, the third thermally conductive member can conduct all heat of the hot end parallel to the panel, and then conduct the heat to the first thermally conductive member, thereby improving cooling efficiency.

In a possible implementation, the second thermally conductive member or the third thermally conductive member is a thermally conductive structure made of a thermally conductive material that is deformable under pressure.

Apparently, in the foregoing implementation, when one of surfaces of the transmit coil and the semiconductor refrigeration chip that are opposite to each other is uneven because of deformation, a pit, or a bump, the second thermally conductive member is pressed by the transmit coil and the semiconductor refrigeration chip to deform, so as to be evenly in contact with both the transmit coil and the semiconductor refrigeration chip, thereby improving heat conduction efficiency. The third thermally conductive member is a thermally conductive structure made of a thermally conductive material that is deformable under pressure. The third thermally conductive member is pressed by the first thermally conductive member and the semiconductor refrigeration chip to deform, so as to be evenly in contact with both the first thermally conductive member and the semiconductor refrigeration chip, thereby improving heat conduction efficiency.

### BRIEF DESCRIPTION OF DRAWINGS

FIG. 1 is a schematic diagram of a wireless charging device according to an embodiment of this application:

FIG. 2 is a schematic sectional view of the wireless charging device shown in FIG. 1:

FIG. 3 is a schematic diagram of a wireless charging device according to another embodiment of this application:

FIG. 4 is a schematic sectional view of the wireless charging device shown in FIG. 3;

FIG. 5 is a schematic diagram of a wireless charging device according to another embodiment of this application; and

FIG. 6 is a schematic sectional view of the wireless charging device shown in FIG. 5.

### DESCRIPTION OF REFERENCE SIGNS OF MAIN COMPONENTS

Wireless charging device: 100, 100a, 100b; Housing: 10, 10a, 10b; Panel: 11; Support part: 12; Spacing part: 13; Air vent: 101; First cavity: 102; First segment: 1021; Second segment: 1022; Second cavity: 103; Third cavity: 104; Air intake vent: 105; Air exhaust vent: 106; Fastener: 14; Transmit coil: 20; Coil body: 21; Soft magnet: 23; Heat dissipation assembly: 30; Semiconductor refrigeration chip: 31, 31a, 31b; Cold end: 311, 311a, 311b; Hot end: 312, 312a, 312b; Fan: 32, 32a, 32b; First thermally conductive member: 33; Second thermally conductive member: 34; Third thermally conductive member: 35; Circuit board: 40; Electronic device: 200.

### DESCRIPTION OF EMBODIMENTS

To further describe technical means and effects that are used by this application to achieve a predetermined application objective, the following describes embodiments with reference to the accompanying drawings and implementations. Apparently, the described embodiments are merely some rather than all of the embodiments of this application.

Unless otherwise defined, all technical and scientific terms used in this specification have the same meaning as those commonly understood by persons skilled in the art of this application. The terms used in the specification of this application are merely intended to describe specific embodiments, and are not intended to limit this application.

Some implementations of this application are described in detail below with reference to the accompanying drawings. If there is no conflict, the following embodiments and features in the embodiments may be mutually combined.

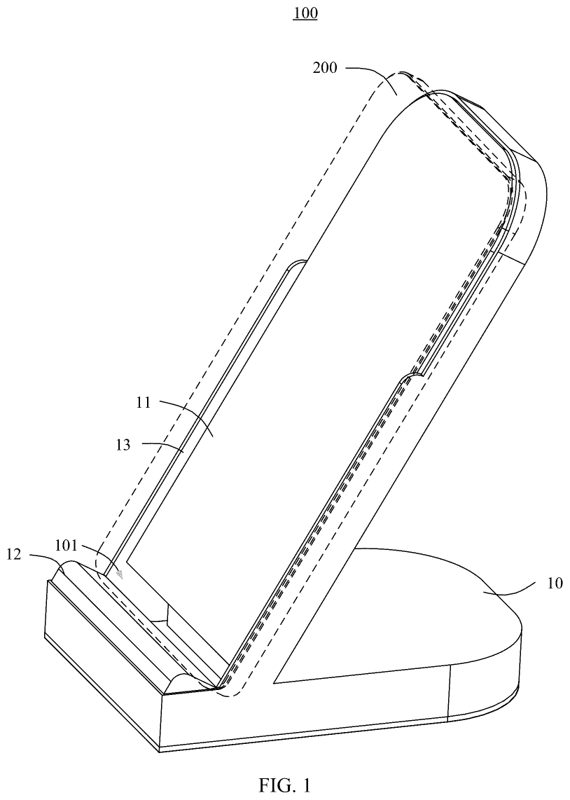

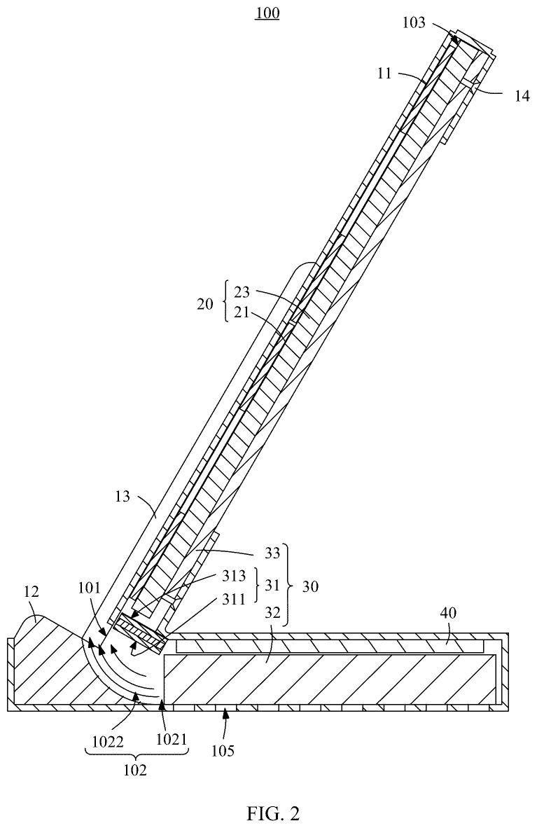

Referring to FIG. 1 and FIG. 2, this application provides a wireless charging device 100. The wireless charging device 100 is configured to charge an electronic device 200. The electronic device 200 may be a mobile phone, a tablet personal computer (Tablet Personal Computer), a laptop computer (Laptop Computer), a personal digital assistant (Personal Digital Assistant. PDA), a mobile Internet device (Mobile Internet Device. MID), a wearable device (Wearable Device), or the like.

The wireless charging device 100 includes a housing 10, a transmit coil 20, and a heat dissipation assembly 30. A first cavity 102 and a second cavity 103 are disposed in the housing 10. The second cavity 103 is located above the first cavity 102. The housing 10 is provided with a panel 11. The transmit coil 20 is disposed in the first cavity 102, and is in contact with one side of the panel 11. The wireless charging device 100 generates an alternating current electromagnetic field when the transmit coil 20 is connected to an alternating current power supply, so that a coil in the electronic device 200 generates an inducting voltage in the alternating current magnetic field, thereby implementing wireless charging on the electronic device 200.

The electronic device 200 is placed on the housing 10, and the electronic device 200 is at a distance from the panel 11, as shown in FIG. 1. The heat dissipation assembly 30 includes a semiconductor refrigeration chip 31 and a fan 32. The semiconductor refrigeration chip 31 and the fan 32 are separately disposed in the first cavity 102. The housing 10 is further provided with an air vent 101 communicating with the first cavity 102. The air vent 101 is located under the panel 11. The semiconductor refrigeration chip 31 is made based on a Peltier (Peltier) effect of a semiconductor material. The Peltier effect refers to a phenomenon that one end absorbs heat and the other end dissipates heat when a direct current passes through a galvanic couple formed by two different semiconductor materials in series. The semiconductor refrigeration chip 31 made based on this principle includes a cold end 311 and a hot end 312 that are on opposite sides. The cold end 311 may cool adjacent components, and heat is transferred through the hot end 312. The semiconductor refrigeration chip 31 is disposed on the housing 10, and is located in the first cavity 102. The hot end 312 of the semiconductor refrigeration chip 31 is fixedly connected to the housing 10, and the cold end 311 protrudes into the first cavity 102. The air blown by the fan 32 passes through the cold end 311 and is blown out from the air vent 101.

A temperature of the air that passes through the cold end 311 is reduced, and the air passes between the panel 11 and the electronic device 200 to reduce a temperature of the electronic device 200.

The panel 11 is made of an insulating and heat-insulation material (for example, a glass fiber or a vacuum plate). Heat generated by the transmit coil 20 is not conducted between the panel 11 and the electronic device 200 through the panel 11, so that cooling of the electronic device 200 by the air blown from the air vent 101 is improved.

It may be understood that, in another embodiment, the panel 11 may alternatively be made of an insulating and thermally conductive non-metallic material, such as a carbon fiber material or a ceramic material. The air blown from the air vent 101 may cool both the panel 11 and the electronic device 200, and the cooling of the panel 11 reduces a temperature of the transmit coil 20.

The fan 32 and the semiconductor refrigeration chip 31 are located in the first cavity 102. The semiconductor refrigeration chip 31 is closer to the air vent 101 than the fan 32. An air intake vent 105 is disposed at the bottom of the housing 10. The air intake vent 105 is located on a side that is of the first cavity 102 and that is away from the second cavity 103. The air intake vent 105 communicates with the first cavity 102. Air enters the first cavity 102 from the air intake vent 105, and the fan 32 guides the air to blow between the electronic device 200 and the panel 11 through the air vent.

It may be understood that, in another embodiment, the air intake vent 105 may alternatively be disposed on a side that is of the first cavity 102 and that is away from the air vent 101. A position of the air intake vent 105 on the first cavity 102 may be set based on an air guiding direction of the fan 32, provided that the fan 32 can guide air entering from the air intake vent 105 to be blown out of the air vent 101.

There is one semiconductor refrigeration chip 31 and the hot end 312 of the semiconductor refrigeration chip 31 is disposed on a cavity wall that is of the first cavity 102 and that faces the second cavity 103, but is not limited thereto. For example, in another embodiment, there are two semiconductor refrigeration chips 31. The two semiconductor refrigeration chips 31 are disposed opposite to each other on two opposite cavity walls of the first cavity 102, and cold ends 311 of the two semiconductor refrigeration chips are disposed opposite to each other. The air blown by the fan 32 is blown to the cold ends 311 of the two semiconductor refrigeration chips 31, so that the air blown between the electronic device 200 and the panel 11 is quickly cooled, thereby improving efficiency of reducing a temperature of the electronic device 200.

The housing 10 is further provided with a support part 12 on a side of the air vent 101. The support part 12 is configured to support the electronic device 200. The housing 10 is further provided with a spacing part 13. There are two spacing parts 13. The two spacing parts 13 are disposed at intervals and protrude from the panel 11. The spacing part 13 is configured to be in contact with the electronic device 200, so that there is a distance between the electronic device 200 and the panel 11.

It may be understood that, in another embodiment, a quantity of spacing parts 13 may be one or another number. Provided that the spacing part 13 protrudes from the panel 11, the electronic device 200 is placed on the housing 10, and is in contact with the spacing part 13, so that there is a distance between the electronic device 200 and the panel 11.

The first cavity 102 includes a first segment 1021 and a second segment 1022 that communicate with each other. The fan 32 is disposed in the first segment 1021. The second segment 1022 is closer to the air vent 101 than the first segment 1021. The second segment 1022 extends upward along a curve from the first segment 1021 to the air vent 101, so as to guide the air blown by the fan 32 to blow out from the air vent 101, and reduce a force of the air blown by the air vent 101 on the electronic device 200 placed on the housing 10. The fan 32 blows air in a direction of the first segment 1021 toward the second segment 1022.

It may be understood that, in another embodiment, the first segment 1021 may alternatively be obliquely disposed along a straight line, or the first segment 1021 extends from the second segment 1022 to the air vent 101 along two straight paths that intersect along an L-shape or a V-shape.

The heat dissipation assembly 30 further includes a first thermally conductive member 33. The first thermally conductive member 33 is disposed on the housing 10, and is located in the first cavity 102. The panel 11, the transmit coil 20, and the first thermally conductive member 33 are sequentially stacked, and sequentially transmit heat.

The first thermally conductive member 33 may be separated from the housing 10, and the first thermally conductive member 33 is exposed from the housing 10 and is in contact with air outside the housing 10. The first thermally conductive member 33 may be in an integrated structure with the housing 10, and the first thermally conductive member 33 is in contact with the air outside the housing 10.

Heat of the transmit coil 20 is conducted to the first thermally conductive member 33, and the first thermally conductive member 33 dissipates the heat to the outside of the first cavity 102.

It may be understood that, in another embodiment, the first thermally conductive member 33 may alternatively be omitted.

The transmit coil 20 includes a coil body 21 and a soft magnet 23. The panel 11, the coil body 21, and the soft magnet 23 are sequentially disposed. The soft magnet 23 can improve strength of a magnetic field generated when the coil body 21 is energized.

The soft magnet 23 is made of a soft magnetic material, for example, the soft magnet 23 may be made of a ferrite or an iron-based amorphous alloy.

The transmit coil 20 and the first thermally conductive member 33 may be separately connected to the housing 10 in an adhesive manner, but is not limited thereto. For example, as shown in FIG. 2, the first thermally conductive member 33 is locked on the housing 10 by using a fastener 14 such as a screw; so that the first thermally conductive member 33 and the panel 11 are respectively pressed against both sides of the transmit coil 20, and the transmit coil 20 and the first thermally conductive member 33 are fastened to the housing 10, thereby avoiding impact of heat-conducting property of adhesive on heat conduction efficiency of the transmit coil 20 and the first thermally conductive member 33.

The wireless charging device 100 further includes a circuit board 40. The circuit board 40 is disposed on the housing 10, and is located in the first cavity 102. The circuit board 40 is located on a side that is of the fan 32 and that is away from the air intake vent 105, and the circuit board 40 is electrically connected to the transmit coil 20, the fan 32, and the semiconductor refrigeration chip 31, so as to control the transmit coil 20, the fan 32, and the semiconductor refrigeration chip 31 to operate.

In the wireless charging device 100, the air blown by the fan 32 passes through the cold end 311 of the semiconductor refrigeration chip 31, so that the air cools down and passes through the air vent 101 to flow between the panel 11 and the electronic device 200, thereby improving a cooling effect of the electronic device 200.

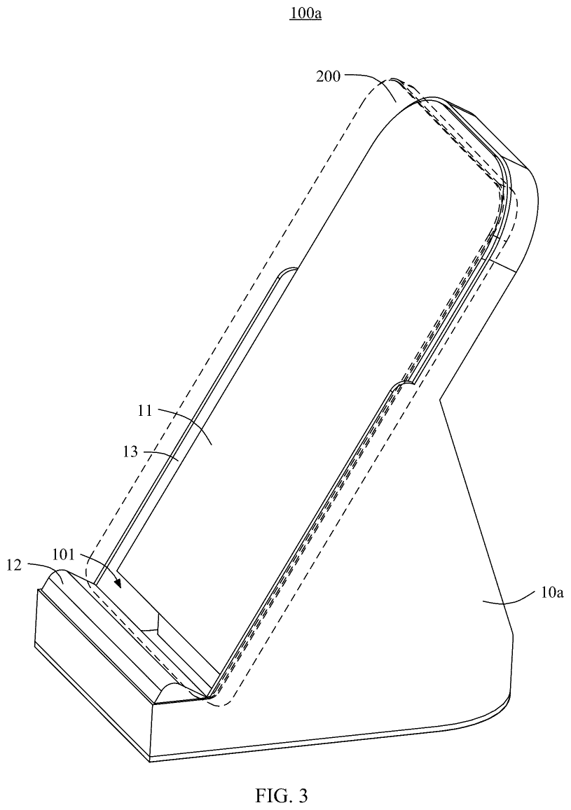

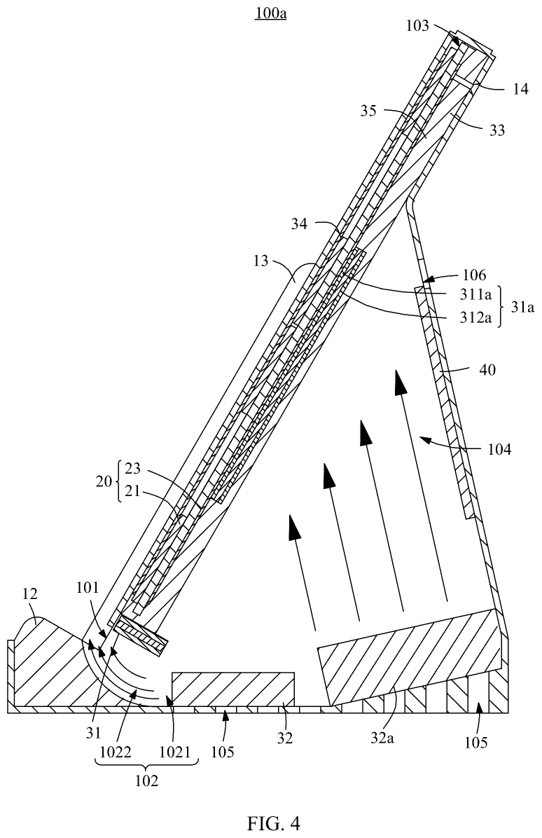

Referring to FIG. 3 and FIG. 4, a difference between a wireless charging device 100a in another embodiment and the wireless charging device 100 lies in that the wireless charging device 100a further includes another fan 32a and another semiconductor refrigeration chip 31a, and a structure of a housing 10 of the wireless charging device 100a is different from a structure of a housing 10a of the wireless charging device 100a.

The semiconductor refrigeration chip 31a is stacked on a side of a transmit coil 20 and a first thermally conductive member 33. The fan 32a is disposed on a first housing, and is located in a first cavity 102, but is not limited thereto. The fan 32a is located on a side that is of the fan 32a and that is away from the semiconductor refrigeration chip 31a.

The housing 10a is further provided with a third cavity 104 and an air exhaust vent 106. The third cavity 104 communicates with both the first cavity 102 and a second cavity 103. The third cavity 104 is located above the first cavity 102, and is located on a side of the second cavity 103. The air exhaust vent 106 is located on a side that is of the third cavity 104 and that is away from the first thermally conductive member 33. The air blown by the fan 32a can be blown to the first thermally conductive member 33 and discharged from the air exhaust vent 106, thereby reducing a temperature of the first thermally conductive member 33, and then reducing a temperature of the transmit coil 20.

The first thermally conductive member 33 is obliquely disposed above the fan 32a, to increase projection of the first thermally conductive member 33 on the fan 32a, so that the air blown by the fan 32a may be directly blown to a larger area of the first thermally conductive member 33, thereby improving efficiency of reducing the temperature of the first thermally conductive member 33.

The air blown by the fan 32a and the air blown by the fan 32 respectively are respectively blown to the first thermally conductive member 33 and between the electronic device 200 and the panel 11, so that both the electronic device 200 and the wireless charging device 100 are cooled, thereby improving cooling efficiency.

The wireless charging device 100a further includes a circuit board 40. The circuit board 40 is disposed on the housing 10a, and is located on a cavity wall that is of the third cavity 104 and that is away from the first thermally conductive member 33. The circuit board 40 is electrically connected to the transmit coil 20, the fan 32a, and the fan 32a. The circuit board 40 is obliquely disposed above the fan 32a, so that the air blown by the fan 32a can be blown to the circuit board 40, and the circuit board 40 is cooled.

The wireless charging device 100a further includes a second thermally conductive member 34, and the second thermally conductive member 34 is disposed between the transmit coil 20) and the semiconductor refrigeration chip 31a. The second thermally conductive member 34 is a thermally conductive structure made of a thermally conductive material that is deformable under pressure. For example, the second thermally conductive member 34 is a sheet-like structure made of thermally conductive silicone. Hardness of the transmit coil 20 and hardness of the semiconductor refrigeration chip 31a are greater than hardness of the second thermally conductive member 34. When one of surfaces of the transmit coil 20 and the semiconductor refrigeration chip 31a that are opposite to each other is uneven because of deformation, a pit, or a bump, the second thermally conductive member 34 is pressed by the transmit coil 20 and the semiconductor refrigeration chip 31a to deform, so as to be evenly in contact with both the transmit coil 20 and the semiconductor refrigeration chip 31a, thereby improving heat conduction efficiency. It may be understood that, in another embodiment, the second thermally conductive member 34 may alternatively be made of a hard thermally conductive material. When an area of a cold end 311a of the semiconductor refrigeration chip 31a parallel to the panel 11 is smaller than an area of the second thermally conductive member 34 parallel to the panel 11, the second thermally conductive member 34 can conduct all heat of the transmit coil 20 parallel to the panel 11, and then conduct the heat to the semiconductor refrigeration chip 31a, thereby improving cooling efficiency.

It may be understood that, in another embodiment, when an area of the cold end 311a and the hot end 312a that are of the semiconductor refrigeration chip 31a parallel to the panel 11 is more than 50% of an area of the transmit coil 20 parallel to the panel 11, both the first thermally conductive member 33 and the second thermally conductive member 34 may be omitted.

The heat dissipation assembly 30 further includes a third thermally conductive member 35, and the third thermally conductive member 35 is disposed between the semiconductor refrigeration chip 31a and the first thermally conductive member 33. The third thermally conductive member 35 is a thermally conductive structure made of a thermally conductive material that is deformable under pressure. The third thermally conductive member 35 is pressed by the first thermally conductive member 33 and the semiconductor refrigeration chip 31a to deform, so as to be evenly in contact with both the first thermally conductive member 33 and the semiconductor refrigeration chip 31a, thereby improving heat conduction efficiency.

It may be understood that, in another embodiment, the semiconductor refrigeration chip 31a may alternatively be omitted. Heat of the transmit coil 20 is conducted to the first thermally conductive member 33, and the fan 32a blows air to the first thermally conductive member 33, which can also reduce a temperature of the first thermally conductive member 33.

In the wireless charging device 100a, the air blown by the fan 32 passes through the cold end 311 of the semiconductor refrigeration chip 31, so that the air cools down and passes through the air vent 101 to flow between the panel 11 and the electronic device 200, thereby improving a cooling effect of the electronic device 200. In the wireless charging device 100a, the air is blown to the first thermally conductive member 33 through the fan 32a, a temperature of the transmit coil 20 is reduced through heat conduction between the first thermally conductive member 33 and the transmit coil 20. The wireless charging device 100a can cool both the electronic device 200 and the transmit coil 20.

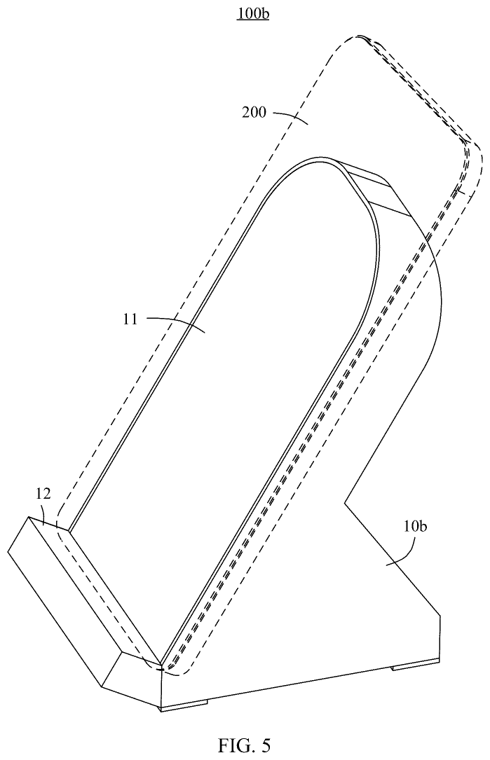

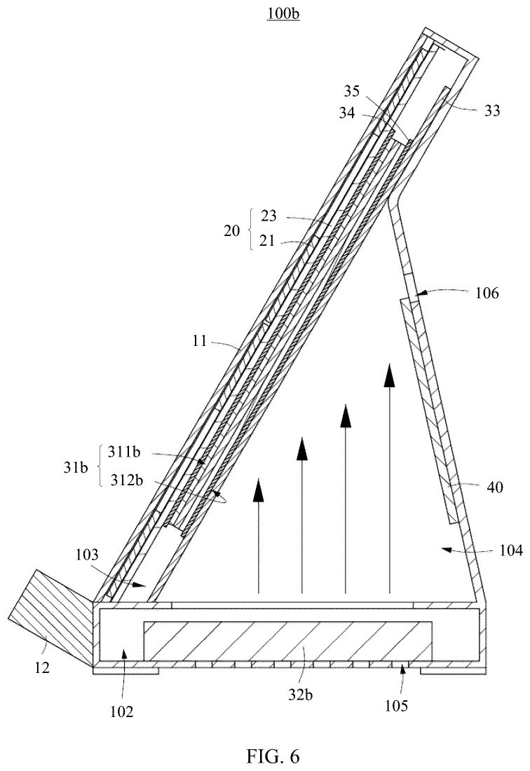

Referring to FIG. 5 and FIG. 6, in still another embodiment, a wireless charging device 100b includes a housing 10ab, a transmit coil 20, and a heat dissipation assembly 30. The housing 10ab is provided with a panel 11. The heat dissipation assembly 30 includes a semiconductor refrigeration chip 31b, a first thermally conductive member 33, and a fan 32b. The semiconductor refrigeration chip 31b includes a cold end 311b and a hot end 312b. The panel 11, the transmit coil 20, the semiconductor refrigeration chip 31b, and the first thermally conductive member 33 are sequentially stacked. The cold end 311b faces the transmit coil 20. The hot end 312b faces the first thermally conductive member 33. The fan 32b is disposed in the housing 10ab. The first thermally conductive member 33 is obliquely disposed above the fan 32b, to increase projection of the first thermally conductive member 33 on the fan 32b, so that the air blown by the fan 32b may be directly blown to a larger area of the first thermally conductive member 33, thereby improving efficiency of reducing a temperature of the first thermally conductive member 33.

The panel 11 is made of an insulating and thermally conductive non-metallic material, such as a carbon fiber material or a ceramic material.

The housing 10ab is further provided with a support part 12 located under the panel 11. The support part 12 is configured to support the electronic device 200, so that the electronic device 200 is placed on the housing 10ab, and is in contact with the panel 11.

The air blown by the fan 32b reduces a temperature of the first thermally conductive member 33, to improve a cooling effect of the cold end 311b of the semiconductor refrigeration chip 31b that is in contact with the first thermally conductive member 33, and then reduce temperatures of the transmit coil 20 and the panel 11 that are sequentially in contact with the cold end 311b, thereby reducing a temperature of the electronic device 200 that is in contact with the panel 11.

A first cavity 102, a second cavity 103, and a third cavity 104 are disposed in the housing 10ab. The second cavity 103 is located above the first cavity 102. The fan 32b is located in the first cavity 102. The transmit coil 20, the semiconductor refrigeration chip 31b, and the first thermally conductive member 33 are sequentially disposed in the second cavity 103. The housing 10ab is further provided with an air exhaust vent 106, and the air exhaust vent 106 communicates with the third cavity 104. An air intake vent 105 communicating with the first cavity 102 is disposed at the bottom of the housing 10ab. The third cavity 104 communicates with both the first cavity 102 and a second cavity 103.

The third cavity 104 is located above the first cavity 102, and is located on a side of the second cavity 103, to enable the air blown by the fan 32b to enter the third cavity 104 from the first cavity 102 and be directly blown to the first thermally conductive member 33, so as to effectively reduce a temperature of the hot end 312b of the semiconductor refrigeration chip 31b, so that a temperature of the cold end 311b of the semiconductor refrigeration chip 31b is maintained at a lower temperature, or a low-temperature state is maintained for a longer time. Air enters the first cavity 102 from the air intake vent 105, is blown out from the fan 32b and is blown to the first thermally conductive member 33, and then is discharged from the air exhaust vent 106. The wireless charging device 100b further includes a circuit board 40. The circuit board 40 is disposed on the housing 10ab, and is located in the third cavity 104. The circuit board 40 is electrically connected to the transmit coil 20 and the fan 32b. The circuit board 40 is obliquely disposed above the fan 32b, so that the air blown by the fan 32b can be blown to the circuit board 40, and the circuit board 40) is cooled.

The wireless charging device 100b further includes a second thermally conductive member 34, and the second thermally conductive member 34 is disposed between the transmit coil 20 and the semiconductor refrigeration chip 31b. The second thermally conductive member 34 is a thermally conductive structure made of a thermally conductive material that is deformable under pressure. For example, the second thermally conductive member 34 is a sheet-like structure made of thermally conductive silicone. Hardness of the transmit coil 20 and hardness of the semiconductor refrigeration chip 31b are greater than hardness of the second thermally conductive member 34. When one of surfaces of the transmit coil 20 and the semiconductor refrigeration chip 31a that are opposite to each other is uneven because of deformation, a pit, or a bump, the second thermally conductive member 34 is pressed by the transmit coil 20 and the semiconductor refrigeration chip 31b to deform, so as to be evenly in contact with both the transmit coil 20 and the semiconductor refrigeration chip 31b, thereby improving heat conductive efficiency.

It may be understood that, in another embodiment, the second thermally conductive member 34 may alternatively be made of a hard thermally conductive material. When an area of the cold end 311b of the semiconductor refrigeration chip 31b parallel to the panel 11 is smaller than an area of the second thermally conductive member 34 parallel to the panel 11, the second thermally conductive member 34 can conduct all heat of the transmit coil 20 parallel to the panel 11, and then conduct the heat to the semiconductor refrigeration chip 31b, thereby improving cooling efficiency.

It may be understood that, in another embodiment, when an area of the cold end 311b and the hot end 312b that are of the semiconductor refrigeration chip 31b parallel to the panel 11 is more than 50% of an area of the transmit coil 20 parallel to the panel 11, both the first thermally conductive member 33 and the second thermally conductive member 34 may be omitted.

The heat dissipation assembly 30 further includes a third thermally conductive member 35, and the third thermally conductive member 35 is disposed between the semiconductor refrigeration chip 31b and the first thermally conductive member 33. When an area of the hot end 312b of the semiconductor refrigeration chip 31b parallel to the panel 11 is smaller than an area of the third thermally conductive member 35 parallel to the panel 11, the third thermally conductive member 35 can conduct all heat of the hot end 312b parallel to the panel 11, and then conduct the heat to the first thermally conductive member 33, thereby improving cooling efficiency.

The third thermally conductive member 35 is a thermally conductive structure made of a thermally conductive material that is deformable under pressure. The third thermally conductive member 35 is pressed by the first thermally conductive member 33 and the semiconductor refrigeration chip 31b to deform, so as to be evenly in contact with both the first thermally conductive member 33 and the semiconductor refrigeration chip 31b, thereby improving heat conductive efficiency.

The wireless charging device 100b cools the transmit coil 20, the panel 11, and the electronic device 200 that are sequentially in contact with each other through the cold end 311b of the semiconductor refrigeration chip 31b, and the fan 32b blows air to the first thermally conductive member 33, so that the hot end 312b that is in contact with the first thermally conductive member 33 is cooled, thereby improving a cooling effect.

The wireless charging device 100, the wireless charging device 100a, and the wireless charging device 100b may charge the electronic device, and a heat dissipation effect is good in a charging process. For example, the electronic device is a mobile phone, a tablet computer, a headset, a headset case, or a smartwatch.

The foregoing embodiments are merely intended to describe the technical solutions of this application, but are not intended to constitute limitations. Although this application is described in detail with reference to preferred embodiments, persons of ordinary skill in the art should understand that the technical solutions of this application may be modified or equivalent replaced without departing from the spirit and essence of the technical solutions of this application.

1. A wireless charging device, comprising a housing, a transmit coil, and a heat dissipation assembly, wherein the housing is provided with a panel, and the transmit coil is disposed in the housing, and is located on a side of the panel:
the housing is configured to place an electronic device to be charged, and make the electronic device have a distance from the panel; and the housing is provided with an air vent located under the panel; and
the heat dissipation assembly comprises:
a semiconductor refrigeration chip, comprising a cold end and a hot end, wherein the hot end is disposed on the housing; and
a fan, disposed in the housing, and air blown by the fan passes through the cold end and is blown out from the air vent.

2. The wireless charging device according to claim 1, wherein the heat dissipation assembly further comprises another fan and a first thermally conductive member, the first thermally conductive member is disposed on a side that is of the transmit coil and that is away from the panel, the another fan is disposed on the housing, and the another fan blows air to the first thermally conductive member.

3. The wireless charging device according to claim 2, wherein the first thermally conductive member is obliquely disposed above the another fan, and the another fan blows air from an upper side.

4. The wireless charging device according to claim 2, wherein the heat dissipation assembly further comprises another semiconductor refrigeration chip, the another semiconductor refrigeration chip is disposed between the transmit coil and the first thermally conductive member, the cold end faces the transmit coil, and the hot end faces the first thermally conductive member.

5. The wireless charging device according to claim 2, wherein a first cavity and a second cavity are disposed in the housing, and the second cavity is located above the first cavity:
the fan and the another fan are disposed in the first cavity; and
the transmit coil, the semiconductor refrigeration chip, and the first thermally conductive member are sequentially disposed in the second cavity.

6. The wireless charging device according to claim 5, wherein the first cavity comprises a first segment and a second segment, the second segment extends upward along a curve from the first segment to the air vent, the fan is located in the first segment, and the semiconductor refrigeration chip is located in the second segment.

7. The wireless charging device according to claim 5, wherein the wireless charging device further comprises a circuit board, the housing is further provided with a third cavity and an air exhaust vent that communicate with each other, and the third cavity communicates with both the first cavity and the second cavity; and the third cavity is located above the first cavity, and is located on a side of the second cavity; and
the circuit board is electrically connected to the transmit coil, the fan, and the another fan, the circuit board is disposed on the housing, and is located in the third cavity, and air blown by the another fan can be blown to the first thermally conductive member and the circuit board, and is discharged from the air exhaust vent.

8. A wireless charging device, comprising a housing, a transmit coil, and a heat dissipation assembly, wherein the housing is provided with a panel, and the heat dissipation assembly comprises:
a semiconductor refrigeration chip, comprising a cold end and a hot end;
a first thermally conductive member, wherein the panel, the transmit coil, the semiconductor refrigeration chip, and the first thermally conductive member are sequentially stacked, the cold end faces the transmit coil, and the hot end faces the first thermally conductive member; and
a fan, disposed in the housing, wherein the first thermally conductive member is obliquely disposed above the fan.

9. The wireless charging device according to claim 8, wherein a first cavity and a second cavity are disposed in the housing, and the second cavity is located above the first cavity:
the fan is located in the first cavity; and
the transmit coil, the semiconductor refrigeration chip, and the first thermally conductive member are sequentially disposed in the second cavity.

10. The wireless charging device according to claim 9, wherein the wireless charging device further comprises a circuit board, the housing is further provided with a third cavity and an air exhaust vent that communicate with each other, and the third cavity communicates with both the first cavity and the second cavity; and the third cavity is located above the first cavity, and is located on a side of the second cavity; and
the circuit board is electrically connected to the transmit coil and the fan, the circuit board is disposed on the housing, and is located in the third cavity, and air blown by the fan can be blown to the first thermally conductive member and the circuit board, and is discharged from the air exhaust vent.

11. The wireless charging device according to claim 2, wherein the wireless charging device further comprises a second thermally conductive member, and the second thermally conductive member is disposed between the transmit coil and the semiconductor refrigeration chip.

12. The wireless charging device according to claim 11, wherein the heat dissipation assembly further comprises a third thermally conductive member, and the third thermally conductive member is disposed between the semiconductor refrigeration chip and the first thermally conductive member.

13. The wireless charging device according to claim 12, wherein the second thermally conductive member or the third thermally conductive member is a thermally conductive structure made of a thermally conductive material that is deformable under pressure.
